(19) United States
(12) Patent Application Publication
(10) Pub. No.: US 2011/0078536 A1
(43) Pub. Date: Mar. 31, 2011

(54) Using Motion Change Detection to Reduce Power Consumption of Display Systems

(76) Inventors: Kyungtae Han, Portland, OR (US); Zhen Fang, Portland, OR (US)

(21) Appl. No.: 12/567,858

(22) Filed: Sep. 28, 2009

(51) Int. Cl. H03M 13/00; G06K 9/36; G09G 5/36

(52) U.S. Cl. 714/758; 382/236; 345/545; 714/E11.001

(57) ABSTRACT

Image data, such as graphics, text, and video may be conveyed from a host to a remote display. In some cases, an analysis of successive frames may be undertaken to determine whether motion exists between those frames. In one embodiment, this motion detection may involve the use of an error correction code, such as a cyclic recovery check. This may enable a relatively efficient, low cost determination of whether motion is occurring. If motion is not occurring, motion estimation may be simplified in some cases and, in some cases, refreshing of the display may be curtailed, for example, using a local frame buffer associated with the display.

### BACKGROUND

This relates generally to displays for processor-based systems.

While a wide range of efforts have been undertaken to reduce power consumption of processor-based systems, little attention, if any, has been given to reducing the power consumptions of their displays. In fact, the display constitutes one of the most power hungry portions of a platform.

In battery powered applications, the power consumption of displays is even of greater importance. For example, a mobile Internet device (MID) may use a battery powered high definition wireless remote display. The reason for using these high definition remote displays is so that more information can be more effectively displayed than is possible with the relatively small displays associated with the mobile Internet devices. An example of mobile Internet device is a cellular telephone with data capabilities.

### BRIEF DESCRIPTION OF THE DRAWINGS

FIG. 1 is a schematic depiction of a display system with a local frame buffer in accordance with one embodiment;

FIG. 2 is a depiction of a screen scraping based wireless remote display in accordance with one embodiment of the present invention;

FIG. 3 is a depiction of motion estimation in accordance with one embodiment;

FIG. 4 is a schematic depiction of a screen image change detection system in accordance with one embodiment;

FIG. 5 is a schematic depiction of a zero motion detection system in accordance with one embodiment;

FIG. 6 is a schematic depiction of a zero motion detector in accordance with one embodiment of the present invention;

FIG. 7 is a depiction of how the use of a cyclic recovery check code reduces the need to fetch reference frame pixels from a system memory in accordance with one embodiment; and

FIG. 8 is a flow chart for one embodiment.

### DETAILED DESCRIPTION

In accordance with some embodiments of the present invention, a display system may utilize a local frame buffer in order to reduce power consumption. The local frame buffer may help to reduce power consumption, for instance, when no motion is detected between frames. The need to refresh a frame buffer may be reduced where it is determined that motion is not present.

Also, information to be displayed may be compressed before sending it to the display. If little motion is involved, the information may be compressed in a way that reduces power consumption. Specifically, it may not be necessary to code sequential frames when there is no motion depicted between those frames. In some cases, the amount of compression that is needed may be reduced. In some embodiments, the detection of motion may be done efficiently and simply using a checksum operation such as a cyclic recovery check.

Mobile platforms are typically used for web browsing, email, and document viewing. In these typical usages, screen images may be static in that they do not depict motion. Many of the displayed frames may be identical to preceding frames. However, to hold an image stable on the screen, current display controllers refresh the display at a fixed rate. Pixel data is fetched across the display interface link from the frame buffer (which is typically part of a system dynamic random access memory (DRAM)). Frame buffer accesses and display interface link transfers caused by display refresh may constitute a large amount of the power consumption on mobile platforms.

In some embodiments, instead of fetching pixel data from the system frame buffer, the display controller refreshes a display through a local frame buffer to reduce power consumption when the next image to be displayed is the same as the currently displayed image that is already stored in a local frame buffer.

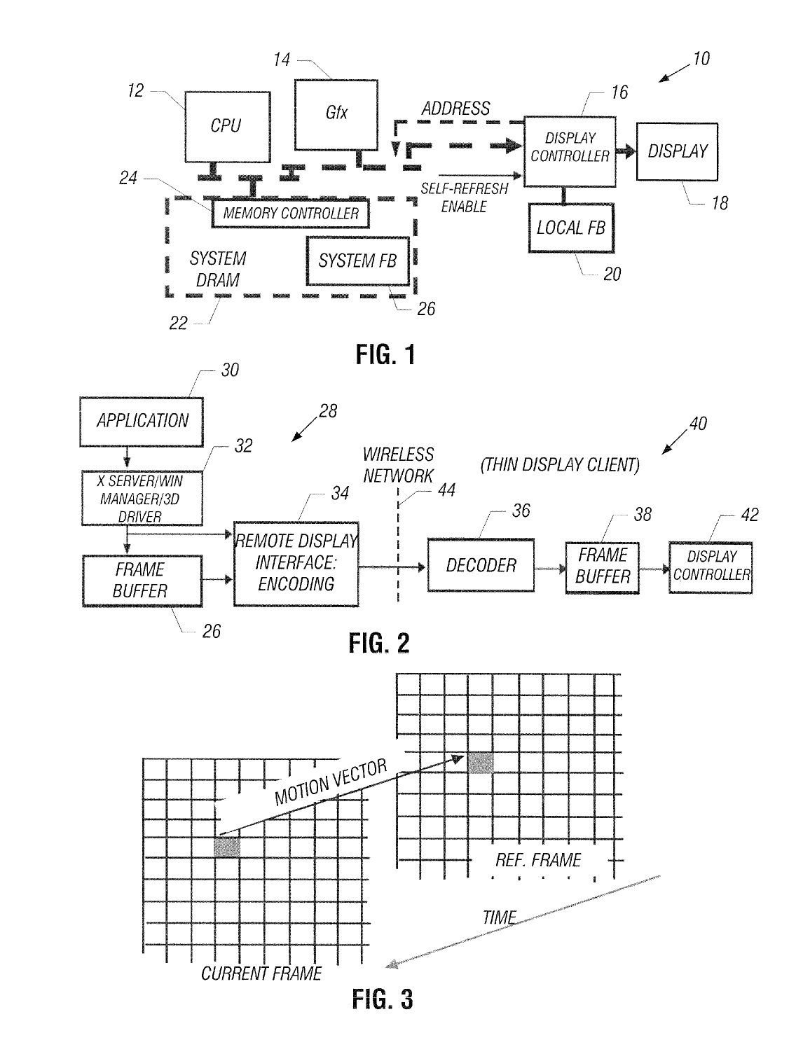

Referring to FIG. 1, a processor-based system 10 may include a processor 12 which, in one embodiment, may be a general purpose processor. The system 10 may be any of a variety of processor-based systems including a personal computer, a mobile computer, a mobile Internet device, a cellular telephone, a camera, a set top box, or a television, to mention a few examples.

The processor 12 may include one or more cores in some embodiments. A graphics controller 14 may, in some embodiments, be provided separately. The graphics controller 14 may be coupled to a display controller 16. In one embodiment, the display controller may be a liquid crystal display controller, although the present invention is not so limited. The controller 16 is coupled to a display 18, such as a liquid crystal display, in one embodiment. The display controller 16 may include a local frame buffer 20.

A memory controller 24 may be coupled to the general purpose processor 12 and the graphics controller 14. The memory controller 24 may be part of a system dynamic random access memory (DRAM) 22, which also includes a system frame buffer 26.

The power consumption of the system DRAM 22 may be reduced, in some embodiments, using a self-refresh mode. The controller 24 can set the self-refresh mode through a signal identified as “self-refresh enable” when the system is inactive for a long time, for example, after there has been no activity from a keyboard or a mouse for a predetermined amount of time, such as two minutes. With self-refresh disabled, data may still be transferred to the display 18 at 60 frames per second, even though most of these frames are identical to one another.

To compensate for the small screen size of mobile Internet devices, such as the device shown in FIG. 2, a high definition wireless remote thin display client 40 may be used. In this usage model, an application 30 runs on the user's handheld device 28, while the picture frames are sent to a large, intelligent display nearby through a wireless link 44.

Among the mechanisms to intercept and transfer commands and data from a host or sender 28 to the thin display client or receiver 40, screen scraping sends pre-rendered frames from the application server to the receiver display instead of sending commands for the receiver to redraw the graphics. Because of its advantage in rendering three dimensional frames on thin display clients, screen scraping may be advantageous.

For many applications, such as high definition display and radio on mobile Internet devices, some form of data compression may be used to reduce both network bandwidth requirements and transmission radio power. As a result, displays may have hardware with MPEG/H.264 decoders for video playback. See H.264/MPEG-4 AVC specification, dated 03/09, prepared by the ITU-T Video Coding Experts Group and available from International Telecommunications Union, Geneva, Switzerland. Of course, other encoding and decoding schemes can also be used. At the same time, cameras, together with video encoding accelerators, may be available in some mobile Internet devices. The video encoding hardware provides a data compression utility. The motion estimation of MPEG and H.264 coding may reduce temporal redundancy between two frames and can be used for wireless remote display data compression.

Thus, in FIG. 2, the application 30 is coupled to a server/windows manager/three dimensional driver 32. The driver 32 is coupled to a system frame buffer 26. The driver 32 and frame buffer 26 may be coupled to a remote display interface 34 that encodes for compression before sending a signal across a wireless network 44.

A thin display client decoder 36 may, in one embodiment, be an MPEG/H.264 decoder on a thin display client 40. The decoder may be coupled to a local frame buffer 38, in turn coupled to a display controller 42, such as a liquid crystal display controller. The display controller 42 is then coupled to a display, such as a liquid crystal display (not shown).

Motion estimation is an inter-frame predictive coding technique used to eliminate a large amount of temporal redundancy between successive video frames. Suppose a reference frame has been encoded and we are trying to encode a current frame. Instead of directly storing and transmitting every pixel, MPEG/H.264 only transmits the difference between the current macroblock and a macroblock of an earlier frame. Motion estimation involves finding a macroblock in an earlier frame that is most similar to the current macroblock and generating a pointer and a residual matrix, as a delta, compared to the reference macroblock.

The test for the difference between the macroblocks is usually a sum of absolute differences (SAD). The pointer, called a motion vector, gives the relative coordinates between the macroblocks. Thus, referring to FIG. 3, a reference frame and a current frame are shown. The motion vector shows how a macroblock, which is shaded in the current frame, compares to the position of the macroblock, which is shaded in a reference frame.

A 16×16 residual matrix gives the difference between the reference macroblock and the current macroblock. The first step of such encoding is the most time consuming step in MPEG and H.264 encoding. The computational intensity of the similarity test is an obstacle to wide deployment of real time, low cost, H.264 hardware encoders.

For a wireless remote display, as one example, a pixel search for motion estimation alone can violate the specified delay target. The delay target is the amount of time that the display has in order to decode the video. As a result, it is generally advantageous to use motion detection with only one macroblock in the reference frame. This candidate reference macroblock has the same coordinates as the current macroblock that is being encoded, in one embodiment.

If the macroblock in the current frame is identical to the candidate macroblock in the reference frame, the current macroblock is encoded as a P or B macroblock to exploit temporal redundancy. Otherwise, the current macroblock is encoded as an I-macroblock, only exploiting intramacroblock data compression.

In cases where most portions of screen content are static, this can result in substantial savings. Most macroblocks end up being encoded as P or B macroblocks, using just a pointer to the same macroblock in its reference frame and an all-zero residual matrix. As a result, MPEG and H.264 encoding is efficient, while still achieving excellent compression ratios, in some embodiments.

A cyclic redundancy check (CRC) is a type of data integrity checksum function that takes as its input a data stream of any length and produces as its output a value of a certain fixed size. Checksums are a type of error correction code that uses a calculated value to test data for errors that occur during data transfers or data storage.

An n-bit cyclic recovery check, applied to a data block of arbitrary length, can detect any single error burst that is not longer than n-bits and can detect a fraction of 1-2⁻ⁿ or longer error bursts.

A cyclic redundancy check may be implemented in hardware in an efficient fashion. For example, an 8 bit cyclic redundancy check engine may use on the order of 50 gates. In addition to cyclic recovery checks, other hash and checksum functions have similar properties to capture random bit changes. Thus, in some embodiments, other hash and checksum functions may be used.

If an exclusive OR value between the cyclic recovery check code for two different macroblocks of data is equal to zero, there is a high probability that these two different macroblocks of data are similar. Otherwise, the two blocks of data are different. If the two blocks of data are two successive frames that are sent to a display, then the cyclic recovery check code serves as an image change detector between the frames.

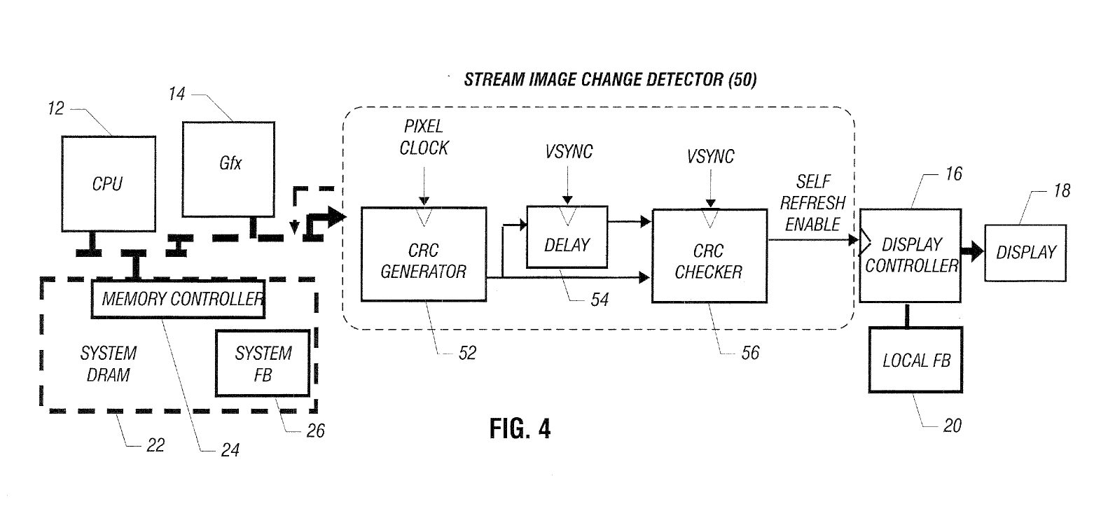

A screen image change detector 50, shown in FIG. 4, may include a cyclic recovery check generator 52, a delay 54, and a cyclic recovery check (CRC) checker 56. The frame pixel data streams through the generator 52 at the pixel clock rate in one embodiment. The generator 52 may generate one value for each frame at the frame rate, which is the same as the vertical synchronization clock, indicated as VSYNC. The delay 54 stores the generated cyclic recovery check value so that it can be compared against the cyclic recovery check value of the next frame. A cyclic recovery checker 56 exclusive ORs the stored cyclic recovery check value in the delay 54 and the new cyclic recovery check value for the current frame. The checker 56 generates the logical value of zero when both cyclic recovery check values are equal in one embodiment. Otherwise, a logical value of one is given, in one embodiment, to indicate that the current frame is different than the previous frame.

The generator 52 may be reset at every VSYNC signal to clear internal values. The one bit change/no change verdict serves as the display refresh enable signal to the display controller 16.

After a no change signal is asserted by the checker 56, the controller 16 stops fetching data from the system frame buffer 26. It goes back to normal refresh mode when the checker 56 de-asserts the no change signal, indicated in FIG. 4, as “self-refresh enable.”

The stream image change detector 50 can detect image changes very efficiently and at low cost in some embodiments. It does not need to throttle the throughput of the display 18. In some embodiments, it only introduces a few pixels worth of initial delay. The silicon cost and power consumption of the extra hardware may be negligible in some embodiments. The detector 50 may not require any change to existing graphics drivers, graphics engines, frame buffers, or controllers, in some cases. In some embodiments, the use of the detector 50 reduces frame buffer accesses caused by unnecessary display refreshes. This enables the system DRAM 22 to stay in the lower power consumption modes for a longer time. For static image contents, reducing the display refresh induced frame buffer accesses helps to increase system memory residency in low power modes which can have significant power consumption benefits.

If two blocks of data are two macroblocks used in motion estimation, one in the current frame and the other in the reference frame, then the cyclic recovery code check may act as a zero-motion detector between macroblocks to simplify the motion estimation operation.

Before motion vectors are derived, zero motion detection between the current macroblock that is being encoded, and the same macroblock, in the previous frame, may be undertaken. If the checksum comparison indicates zero motion between both macroblocks, then the high cost of a macroblock search may be virtually eliminated. This can be thought of as an optimization to the early termination mechanism of existing motion estimation algorithms.

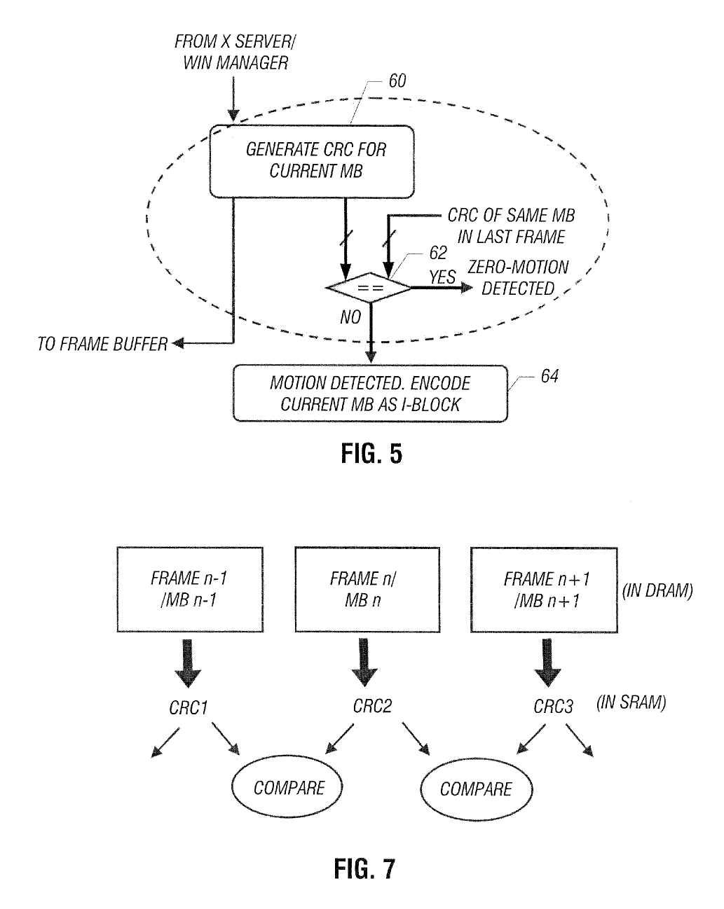

Referring to FIG. 5, the cyclic recovery check may be calculated by hardware for each macroblock (MB) as it is written to the frame buffer, as indicated at 60. There is no need to fetch pixels from the frame buffer in order to compute their cyclic recovery check values. Rather, the pixel data may be intercepted from the driver 32. The cyclic recovery check value is stored in an on-chip memory and, at the same time, exclusive ORed against the cyclic recovery check value of the same macroblock of the previous frame in time, loaded from that on-chip memory. Depending on the result of the exclusive OR operation 62, one of two results may ensue. If the exclusive OR returns zero, this indicates that the macroblocks are identical. A motion vector of (0,0) and an all zero residual matrix for the current macroblock are derived. If the exclusive OR operation returns a 1, then there is a difference, namely, motion, between the two blocks and there is a need to start the baseline encoding process (block 64).

The cyclic recovery check values are compared between the two adjacent frames in time, regardless of whether the previous frame is an I frame, a P frame, or a B frame. The on-chip memory size may be proportional to the supported picture resolution in some embodiments. For example, supporting 1600×1200 pixel pictures may involve 7.3 kilobytes of storage. A static random access memory (SRAM) of this size may consume only a fraction of the power that are correspondingly sized dynamic random access memory may consume. The original frame data is of a size that would be impractical to use a static random access memory. Eliminating the need to retrieve reference frame pixel data from the dynamic random access memory helps to achieve significant power savings in some embodiments.

To further reduce the calculation overhead, some of the pixel components may be ignored between the previous and current frame. For example, when encoding from 4:2:0 YUV, the data ratio between the Y or brightness value and the U and/or V components, the color is 2:1. By using only the U and V components and avoiding checking the Y components, the amount of computation and the SRAM storage may be cut to only one third of what would result from using all the YUV values. The idea is that whatever pixel changes, all three pixel values, Y, U, and V must change. Thus, there is no need, in most cases, to calculate all three YUV values.

When the exclusive OR operation returns a 1, the cyclic recovery check may add an extra amount of computation without generating any benefit. To reduce this overhead, a cyclic recovery check throttling mechanism may turn the cyclic recovery check unit on and off, adapting to the amount of motion in the video.

In one embodiment, the cyclic recovery check is turned off after the total number of times that the exclusive OR operation results in a zero for R successive frames is no more than S, and is turned back on the cyclic recovery check, a (0,0) motion vector has been generated for T successive frames. With this optimization, motion rich contents cause the cyclic recovery check unit to be turned off after the application starts.

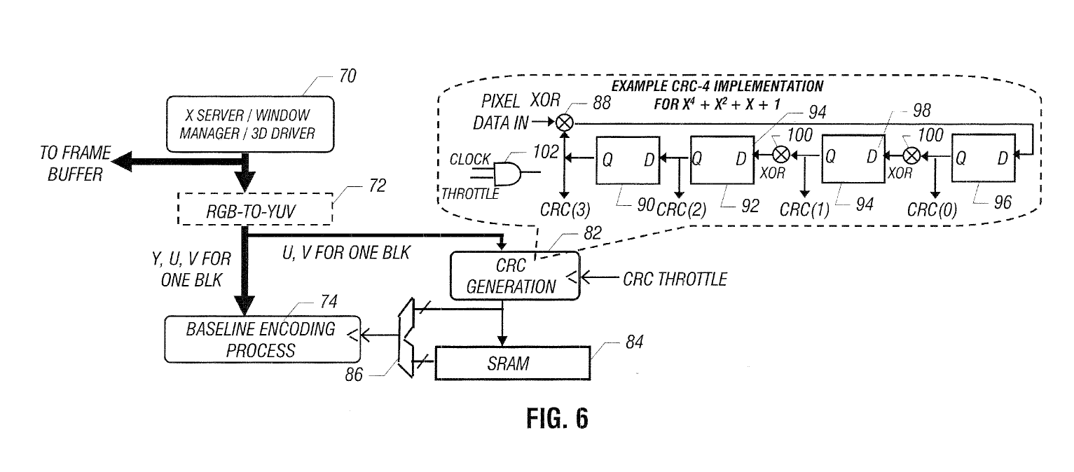

Referring to FIG. 6, the cyclic recovery check augmented video encoder may include the X server/window manager/3D driver 70 coupled to a frame buffer and to an RGB to YUV converter 72. Y, U and/or V values for one block may be passed to a baseline encoding process 74.

U and V values, for one block, are passed to the CRC generation block 82. The block 82 receives the throttle control signal “CRC throttle.” A CRC value is stored in the SRAM 84 so that a comparison can be done between CRC values for successive frames in comparator 86.

The comparison at comparator 86 determines whether or not the two blocks have the same cyclic recovery check code.

The cyclic recovery check generation unit 82 may include an exclusive OR gate 88 that receives the pixel data in. A NAND gate 102 may receive a clock signal and a throttle signal on its inputs in order to activate or deactivate the CRC throttle signal. The CRC generator 82 may include a plurality of gates 90, 92, 94, and 96 in a CRC-4 implementation which, in one embodiment, may be D-type data latches or flip flops 90, 92, 94, and 96, coupled by exclusive OR gates 100. The gates 88 and 100 produce CRC-4 bits CRC(0), CRC(1), CRC(2), and CRC(3). See CRC-4-ITU, available from the International Telecommunications Union, Geneva, Switzerland, Recommendation G.704, page 12. CRC-6, CRC-8, or other bit widths may also be used.

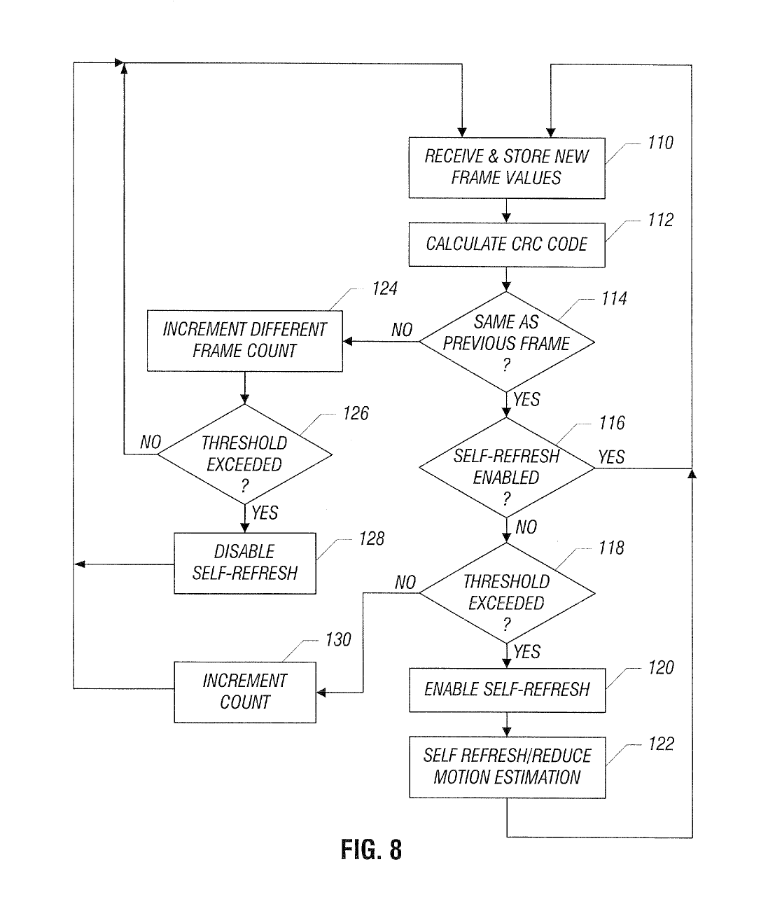

Referring to FIG. 8, some embodiments may be implemented in software, hardware, or firmware. In software based embodiments, the software may be implemented using computer executable instructions stored in a computer readable medium, such as a magnetic, optical, or semiconductor memory. As one example, those instructions may be stored in the system DRAM 22 in FIG. 1.

In accordance with one embodiment, a sequence of operations begins at block 110 with the receipt and storage of new frame values. These frame values may be, for example, Y, U, and V values or less than all of the Y, U, and V values as described previously.

Next, in block 112, a CRC code may be calculated based on the new frame and the previously stored and received frame. If the codes match, as determined in diamond 114, a check at diamond 116 determines whether self-refresh is already enabled. If not, a check at diamond 118 determines whether a threshold has been exceeded, which determines whether or not to enable the soft refresh signal. In one embodiment, the threshold could indicate that a significant number of frames have been the same and, therefore, makes self-refresh reasonable. If so, self-refresh is enabled in block 120 and self-refresh and/or reduced motion estimation may be implemented in block 122.

If the frames are different, as determined in diamond 114, a different frame count may be incremented in block 124. A check at diamond 126 determines whether a threshold is exceeded. If so, self-refresh, if enabled, may be disabled in block 128.

Similarly, if the threshold for enabling self-refresh has not been exceeded, as determined in diamond 118, a count may be incremented (block 130) so that subsequently self-refresh may be enabled if a sufficient count has been achieved.

In some embodiments, power savings may derive from reduced system frame buffer accesses. Pixel-by-pixel comparisons are unnecessary when loading pixel data of the reference frame from the system or frame buffer. The present zero motion detector only needs to fetch cyclic recovery codes from the SRAM 84, as indicated in FIG. 7. Assuming that an average P percent of the whole frames do not change, and that in each of the 1−P percent of the frames in motion in them, Q percent of the macroblocks actually change, we can extrapolate a zero motion percentage of 1−(1−P percent)×Q percent on a macroblock basis. That is, if P=60 and Q=30, then 88 percent of the macroblocks would be zero motion macroblocks. Frame buffer accesses to the DRAM may be reduced. During intervals where there is no mouse or keyboard operation, the DRAM can be put in a low power mode to achieve power savings.

The cyclic recovery check value may be generated when pixels are written to the frame buffer. By contrast, traditional pixel-by-pixel comparisons add to critical path encoding since pixel data of the reference frame are fetched from the frame buffer first.

In some embodiments, using a cyclic recovery code, as opposed to pixelwise comparison, may reduce a significant percentage of the frame buffer reads, saving DRAM access power for typical local display refresh and wireless remote display data compression.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
determining whether motion occurs between successive frames of graphical information using an error correction code.

2. The method of claim 1 wherein using an error correction code includes using a checksum.

3. The method of claim 1 wherein using a checksum includes using a cyclic recovery code.

4. The method of claim 1 including limiting the use of the error correction code for motion detection in response to motion detection.

5. The method of claim 1 including using less than all three color components of the graphical information to determine the error correction code.

6. The method of claim 1 including reducing the refreshing of a display from a system frame buffer based on whether motion is detected.

7. The method of claim 1 including selectively refreshing a display having a built in decoder.

8. The method of claim 7 including selectively refreshing the display for a wirelessly coupled mobile Internet device.

9. The method of claim 1 including reducing the amount of data compression based on motion detection.

10. The method of claim 9 including reducing motion vector generation based on the amount of motion detection.

11. A computer readable medium storing instructions executed by a computer to:
determine an error correction code between two successive frames of image information; and
use said error correction code to control motion vector generation.

12. The medium of claim 11 storing instructions to determine an error correction code that is a checksum.

13. The medium of claim 11 storing instructions to determine an error correction code that is a cyclic recovery code.

14. The medium of claim 11 storing instructions to control the use of said error correction code based on motion between multiple successive frames.

15. A system comprising:
a host including a frame buffer;
a display interface to encode data for transmission over a wireless network;
a display client to receive data over said wireless network, said display client including a decoder and a frame buffer; and
a controller to determine whether motion occurs between successive frames using error correction code.

16. The system of claim 15 wherein said host is a mobile Internet device.

17. The system of claim 15, said controller to reduce an amount of data compression based on said error correction code.

18. The system of claim 15, said controller to reduce motion vector generation based on said error correction code.

19. The system of claim 15, said display client to use said display client frame buffer to refresh a display based on said error correction code.

20. The system of claim 15, said controller to selectively refresh the display client over the wireless network based on said error correction code.
